(19) United States
(12) Patent Application Publication
(10) Pub. No.: US 2012/0237872 A1
(43) Pub. Date: Sep. 20, 2012

(54) BLACK AND WHITE SILVER HALIDE PHOTOSENSITIVE MATERIAL

(75) Inventors: Katsuhisa OHZEKI, Kanagawa (JP); Hidekazu SAKAI, Kanagawa (JP); Hideyuki SHIRAI, Kanagawa (JP); Yuki TESHIMA, Kanagawa (JP)

(73) Assignee: FUJIFILM CORPORATION, Tokyo (JP)

(21) Appl. No.: 13/422,299

(22) Filed: Mar. 16, 2012

(30) Foreign Application Priority Data
Mar. 16, 2011 (JP) 2011-058615

(51) Int. Cl. G03F 7/06; B82Y 30/00

(52) U.S. Cl. 430/271.1; 430/270.1; 977/773

(57) ABSTRACT

A black and white silver halide photosensitive material, having: a support; at least one silver halide emulsion layer; and at least one non-photosensitive layer, wherein both of the silver halide emulsion layer and the non-photosensitive layer are positioned at one side of the support, the non-photosensitive layer includes carbon particles of 35 mg/m² or more, and the non-photosensitive layer is positioned closer to the support than all of the silver halide emulsion layers.

### CROSS-REFERENCE TO RELATED APPLICATION(S)

The present application claims priority from Japanese Patent Application No. 2011-058615 filed on Mar. 16, 2011, the entire content of which is incorporated herein by reference.

### BACKGROUND

1. Field

The present invention relates to a black and white silver halide photosensitive material.

2. Description of Related Art

The black and white silver halide photosensitive material (hereinafter, simply referred to as a “photosensitive material”) is generally exposed to visible light in use to record an image. In this case, one of the most important performances of the photosensitive material is sharpness. The sharpness is seriously diminished due to diffusion of light in the photosensitive material. The diffusion of light in the photosensitive material is largely divided into the following two types. One is long-distance spreading by reflection at a boundary of a layer included in the photosensitive material, which is called halation. The other is scattering due to silver halide particles, oil dispersed substances, or the like in a photosensitive layer, which is called irradiation.

In order to prevent the halation and irradiation, an antihalation layer (AH layer) is formed or a dye is used in the photosensitive material.

In order to prevent the irradiation, it is effective to add a dye to the photosensitive layer, but the dye in the photosensitive layer influences photosensitivity of silver halide particles or serves as a filter, which deteriorates light absorption of the silver halide particles. Therefore, the use of the dye is limited.

In order to absorb reflected light, a dye is generally contained in the antihalation layer. When the dye is fixed in the antihalation layer, a solid disperse dye is used or a pigment is dispersed in oil. The former has a problem in that a part of the solid dispersed substances is dissolved and moved to the photosensitive layer, thereby influencing sensitivity of a silver halide emulsion. The latter requires much labor to prepare stable oil dispersed substances of the pigment.

When these technologies are used, sensitivity after preserving for a predetermined period of time in a high humidity environment is deteriorated due to the influence of the antihalation layer as compared to sensitivity before the preservation which is problematic.

It is possible to form the antihalation layer on a support surface at an opposite side to the photosensitive layer of the photosensitive material, but in this case, an antihalation function is seriously diminished as compared to a case where the antihalation layer is formed at the same side as the photosensitive layer.

It is also possible to prevent halation by using a support material, for example, a so-called colored support obtained by mixing a dye into polyethylene terephthalate or triethyl cellulose and thus the support material is used for a part of photosensitive materials. However, much time and cost are required for the development of such photosensitive material.

Meanwhile, JP-A-2002-99069 discloses a photosensitive material including 5 to 30 mg/m² of dispersed carbon particles.

In the aforementioned status, an antihalation technology, which is not expensive and does not influence a performance of a silver halide emulsion in a photosensitive layer, is required.

In the photosensitive material described in JP-A-2002-99069, since the carbon particles are positioned in the photosensitive layer or closer to a light source than the photosensitive layer, sensitivity is diminished and thus it is not possible to obtain a sufficient antihalation effect.

### SUMMARY

The present invention has been made in an effort to provide a technology of suppressing deterioration in sensitivity of a silver halide photosensitive material due to the passage of time and effectively improving sharpness.

The above problems can be achieved by the following means.
(1) A black and white silver halide photosensitive material, having: a support; at least one silver halide emulsion layer; and at least one non-photosensitive layer, wherein both of the silver halide emulsion layer and the non-photosensitive layer are positioned at one side of the support, the non-photosensitive layer includes carbon particles of 35 mg/m² or more, and the non-photosensitive layer is positioned closer to the support than all of the silver halide emulsion layers.
(2) The black and white silver halide photosensitive material of (1), wherein an average equivalent spherical diameter of silver halide particles included in the silver halide emulsion layer is 0.25 μm or less.
(3) The black and white silver halide photosensitive material of (1), wherein a shape of silver halide particles included in the silver halide emulsion layer is a cube.
(4) The black and white silver halide photosensitive material of (1), wherein the non-photosensitive layer further includes a solid disperse dye.
(5) The black and white silver halide photosensitive material of (1), wherein the non-photosensitive layer is an antihalation layer.
(6) The black and white silver halide photosensitive material of (1), wherein the non-photosensitive layer includes the carbon particles of 50 mg/m² or more.
(7) The black and white silver halide photosensitive material of (1), wherein the carbon particles has 10 nm to 500 nm in diameter.
(8) The black and white silver halide photosensitive material of (1), wherein the silver halide emulsion layer further contains at least one compound selected from the group consisting of chlorauric acid or a salt thereof, gold thiocyanate, and gold thiosulfate.
(9) The black and white silver halide photosensitive material of (1), wherein a thickness of the silver halide emulsion layer is 0.5μm to 5 μm.
(10) The black and white silver halide photosensitive material of (1), wherein a thickness of the non-photosensitive layer is 0.2 μm to 10 μm.

According to the present invention, it is possible to provide the silver halide photosensitive material capable of suppressing deterioration in sensitivity due to the passage of time and effectively improving the sharpness.

### DETAILED DESCRIPTION OF THE INVENTION

The silver halide photosensitive material of the present invention is a black and white silver halide photosensitive material, including: at least one silver halide emulsion layer and at least one non-photosensitive layer, which are on the same plane of a support, wherein the non-photosensitive layer contains 35 mg/m² or more of carbon particles and the non-photosensitive layer including the carbon particles is positioned closer to the support than all the silver halide emulsion layers. The carbon particles may be contained in several layers, but all of the carbon particles may be preferably contained in the non-photosensitive layer. A concentration of the carbon particles of the non-photosensitive layer is preferably 0.5 wt % or more and 6 wt % or less and particularly preferably 0.8 wt % or more and 3 wt % or less. A thickness of the non-photosensitive layer is preferably 0.2 μm or more and 10 μm or less and particularly preferably 1 μm or more and 5 μm or less. The non-photosensitive layer may be an antihalation layer to be described below.

The non-photosensitive layer refers to a layer which does not have photosensitivity and examples thereof may include an antihalation layer and a protective layer.

<Antihalation Layer>

An antihalation layer of the present invention refers to a hydrophilic colloid layer having an absorption wavelength in a photosensitive region of the silver halide emulsion layer and includes a case where the antihalation layer is positioned at an opposite side to the silver halide emulsion layer of a transmissive support and a case where the antihalation layer is positioned between the silver halide emulsion layer and the support regardless of a transmissive or reflective support.

A known dye used as an antihalation dye of a silver halide photographic photosensitive material may be used as dye used for the antihalation layer and type of which is not particularly limited, but a solid disperse dye is particularly preferred to use.

The silver halide photosensitive material of the present invention includes at least one non-photosensitive layer positioned closer to the support than all the silver halide emulsion layers, but includes preferably two or more layers. It is preferable to include at least the antihalation layer and the protective layer at the same side as the silver halide emulsion layer on the support.

In the silver halide photosensitive material of the present invention, when the antihalation layer and the silver halide emulsion layer are coated on the same side of the support, it is preferable to coat the antihalation layer closer to the support than the silver halide emulsion layer. A thickness of one antihalation layer is preferably 0.2 μm or more and 10 μm or less and particularly preferably 1 μm or more and 5 μm or less.

<Carbon Particle>

A particle size (equivalent spherical diameter) of carbon particles influences a performance such as concentration and dispersibility. In the present invention, the particle size of the carbon particles is not particularly limited, but preferably 10 nm to 500 nm and particularly preferably 30 nm to 100 nm.

The carbon particles may form agglomerates of the particles having the above-mentioned size.

A carboxyl group or a hydroxyl group may exist on the surface of the carbon particles so as to be hydrophilic.

Commercially available particles may be used for the carbon particles. For example, MA220 (average primary particle diameter 55 nm: aqueous dispersion) and 230 (average primary particle diameter 30 nm: aqueous dispersion), which are manufactured by Mitsubishi Chemical Corporation, or TOKABLACK manufactured by Tokai Carbon Co., Ltd. may be used. These carbon particles may be used as the aqueous dispersion, but it is preferable to disperse and use the carbon particles into an aqueous gelatin solution.

The silver halide photosensitive material of the present invention includes 35 mg/m² or more of carbon particles in the non-photosensitive layer (more preferably antihalation layer) from the viewpoint of suppressing deterioration in sensitivity due to the passage of time in a high humidity environment. It is preferable to contain 50 mg/m² or more of carbon particles in the non-photosensitive layer. It is preferable to contain 100 mg/m² or less of carbon particles from the viewpoint of a minimum concentration for an image obtained by the silver halide photosensitive material.

<Solid Disperse Dye>

From the viewpoint of increasing sharpness of an image obtained by the silver halide photosensitive material by suppressing halation it is preferred that the silver halide photosensitive material of the present invention further contain a solid disperse dye in the non-photosensitive layer containing the carbon particles positioned closer to the support than all the silver halide emulsion layers or a non-photosensitive layer adjacent to the non-photosensitive layer containing the carbon particles. Particularly, it is preferable to include the solid disperse dye in the same layer as the non-photosensitive layer including the carbon particles. The solid disperse dye is disclosed in Japanese Patent Application Laid-Open Nos. 56-12639, 55-155350, 55-155351, 63-27838 and 63-197943; EP Patent No. 0 015 601, and the like.

The solid disperse dye refers to a dye contained in the silver halide emulsion layer and/or other hydrophilic colloid layers for the purpose of preventing halation, preventing irradiation, improving safety of a safelight, improving discrimination of inner and outer surfaces, and the like and needs to satisfy the following conditions.

(1) Having proper spectral absorption in accordance with the intended use.

(2) Being photographically and chemically inactive. That is, the dye should not have an adverse effect on a performance of the silver halide photographic emulsion layer in terms of the chemical aspect, for example, not causing deterioration in sensitivity, fading of latent image, fogging, or the like.

(3) Not being discolored in a photographic processing process or preventing deleterious coloring from being remained on the photographic photosensitive material after being eluted in a processing liquid or washing water to be processed.

(4) Not being diffused from a dyed layer to other layers. (5) Having excellent stability with the passage of time in a solution or the photographic material not to be discolored.

As the dye satisfying these conditions, a solid dispersed dye described in Japanese Patent Application Laid Open Nos. 56-12639, 55-155350, 55-155351, 63-27838, 63-197943, 4-14035 and 2-264936; EP Patent Nos. 0 299 435, 0 276 566, 0 274 723 and 0 015 601; International Publication No. WO 88/04794, and the like, may be used.

Hereinafter, specific examples of the dye used in the present invention will be described.

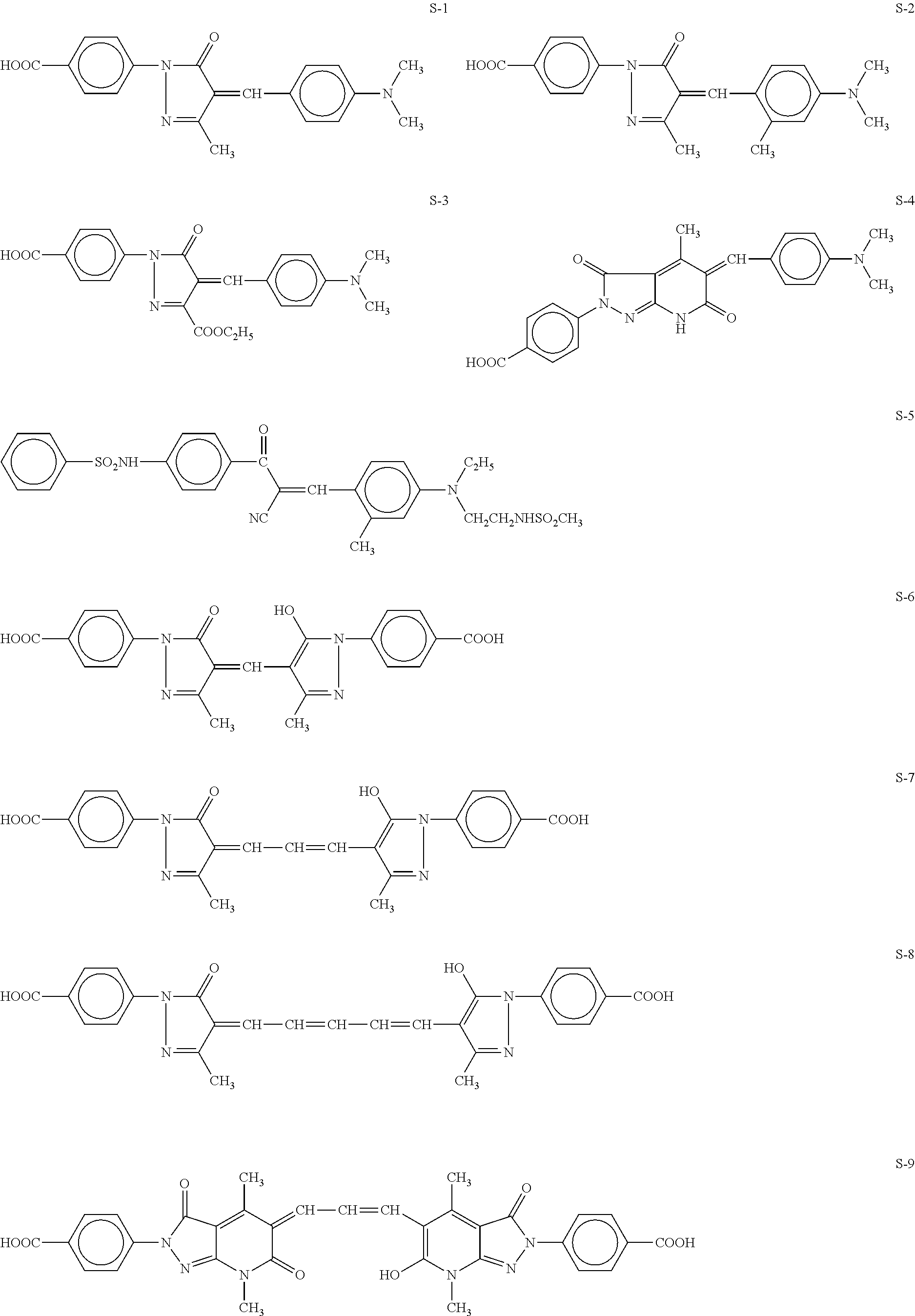

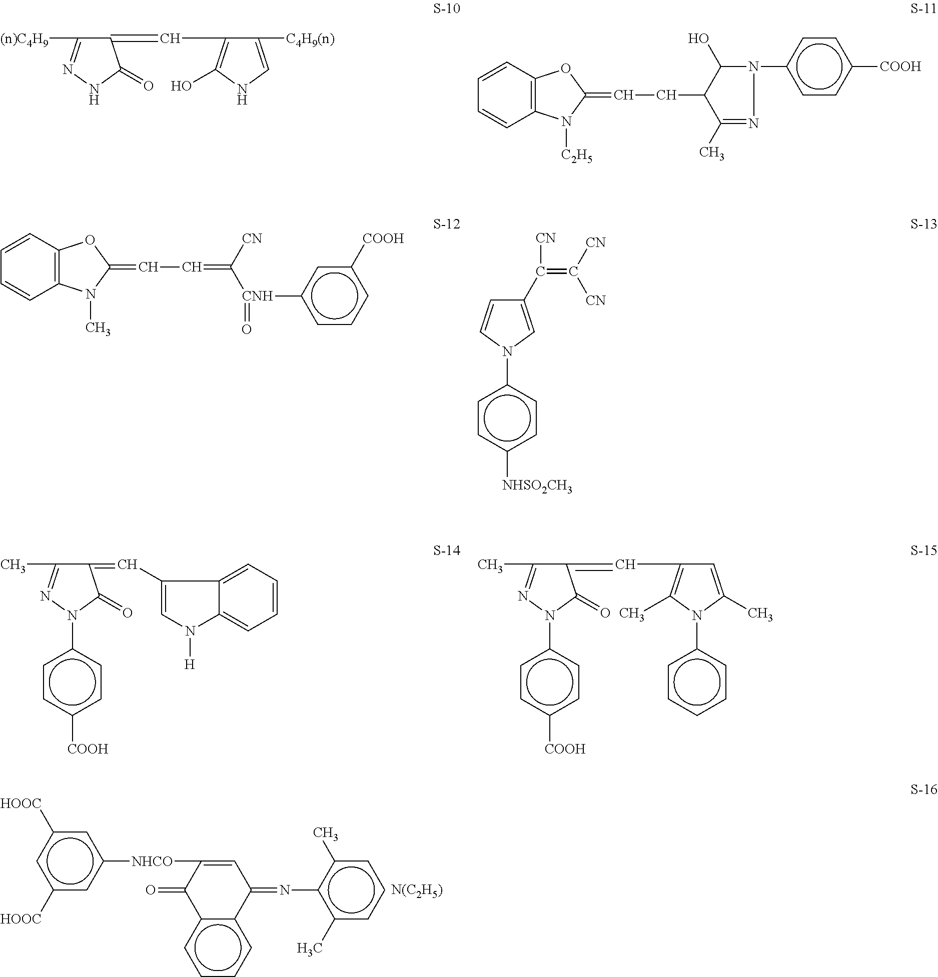

The dye used in the present invention may be easily synthesized according to methods described in International Publication No. WO 88/04794; Europe Patent Application Publication Nos. EP 0 299 435A1, EP 0 276 566A1 and EP 0 274 723A1; Japanese Patent Application Laid-Open Nos. 61-205934, 55-155351, 55-155350, 52-92716, 48-68623, 3-167546, 3-7931 and 2-282244; U.S. Pat. Nos. 4,130,429, 4,040,841, 3,933,798, 3,746,539, 3,486,897, 2,527,583, and the like. In the present invention, a microcrystalline dispersion dye may not exist in a molecular state on a layer to be colored but exists as a solid having a size that cannot be practically diffused in a layer, since solubility of the dye itself is insufficient. A preparation method thereof is described in International Publication No. WO 88/04794, EP Patent Application Publication 0 276 566A1, Japanese Patent Application Laid-Open No. 63-197943, and the like, and the solid is normally prepared by crushing with a ball mill and stabilizing with a surface active agent and gelatin.

The dye in a dispersion of the present invention exists as a fine solid having an average particle diameter in the range of 0.1 μm to 0.6 μm and a variation coefficient of particle size distribution of 50% or less. Herein, particularly preferably, the dye has the average particle size in the range of 0.1 μm to 0.5 μm and more preferably, the dye dispersion has the average particle size of 0.1 μm to 0.5 μm and the variation coefficient of 35% or less. The variation coefficient is represented by a value (S/d) obtained by dividing a standard variation (S) by an average diameter (d) in a distribution represented by a diameter when a projected area is approximated by circular aperture of the same area. An amount of the dye used is 5 mg/m² to 300 mg/m² and particularly preferably 10 mg/m² to 150 mg/m². When the disperse solid of the dye is used as a filter dye or an antihalation dye, any effective amount may be used, but it is preferable to use an amount of the dye to have an optical density in the range of 0.05 to 3.5. Addition of the dye may be allowed for any stage of process before coating processing.

In the photosensitive material to which a method according to the present invention may be applied, at least one silver halide emulsion layer is formed on the support. As a typical example, a silver halide photographic photosensitive material sequentially including an antihalation layer, a silver halide emulsion layer, and a protective layer on the support contains carbon particles and a solid disperse dye in the antihalation layer.

A silver halide emulsion used for the silver halide emulsion layer of the black and white silver halide photosensitive material of the present invention will be described.

<Silver Halide Emulsion>

As a silver halide emulsion, an ortho emulsion, a panchromatic emulsion, an infrared emulsion, emulsions for recording X ray and other invisible light, and the like may be used. When the present invention is used as a material for recording motion picture sound, it is preferable to use a spectrally sensitized emulsion so as to have sufficient sensitivity in a wavelength region corresponding to an exposure wavelength of each sound recording system.

Silver halide particles used in the silver halide emulsion will be described in detail.

The particle of the present invention may have a uniform structure or a so-called core/shell structure including a core part and a shell part surrounding the core part. It is preferred that 90% or more of the core part is silver bromide. The core part may be formed with two or more portions having a different halogen composition. The shell part is preferably 50% or less of the entire particle volume and particularly preferably 20% or less. In the case where silver iodide is contained, it is preferred that more iodide be contained in the shell part (outermost layer). The content of silver iodide in the shell part is preferably 0.1 mole % to 10 mole % and particularly preferably 0.2 mole % to 6 mole %. The content of the silver iodide among the entire particles in the shell part is preferably 6 mole % or less and particularly preferably 2 mole % or less.

Flat particles of the silver halide of the present invention have an average particle size (equivalent spherical diameter) of preferably 0.25 μm or less and particularly preferably 0.1 μm to 0.25 μm from the viewpoint of enhancing sharpness. In the present invention, it is possible to achieve high image quality (enhancement of sharpness) and prevention of desensitization due to the passage of time with high humidity environment at the same time by making the particle size small and using the carbon particles.

A particle size distribution of the silver halide particles of the present invention may be either poly-dispersed or mono-dispersed, but the mono-disperse is more preferable.

A shape of the silver halide particles of the present invention is not particularly limited, but is preferably a cube from the viewpoint of sharpness, pigment adsorption, and morphological stability.

As the silver halide particles of the present invention, an ion of metal selected from the Group VIII metals on the Periodic Table, i.e., osmium, iridium, rhodium, platinum, ruthenium, palladium, cobalt, nickel, and iron, or a complex ion thereof may be used either alone or in combination. These metals may be used in plural kinds.

The metal ion donating compounds may be contained in the silver halide particles of the present invention by adding the compounds into an aqueous gelatin solution, an aqueous halide solution, an aqueous silver salt solution, or other aqueous solutions which become a dispersion medium at the time of forming the silver halide particles, or adding the compounds to the silver halide emulsion in a form of silver halide particulates containing metal ions in advance to dissolve the emulsion, or the like. In order to contain the metal ions in the particles, the metal ions may be added at any time before forming the particles, when forming the particles, and immediately after forming the particles and the addition timing may be changed depending on a position of the particles where the metal ions are contained and the amount of the contained metal ions.

It is preferred that the used metal ion donating compounds are localized in the surface layer of the silver halide particles, which corresponds to a region from the surface of the silver halide particle to 50% in volume of the silver halide particle. The metal ion donating compounds are contained in the surface layer in amount of 50 mole % or more, preferably 80 mole % or more, more preferably 100 mole %. The volume of the surface layer is preferably 30% or less. The localizing of the metal ions on the surface layer is advantageous for suppressing an increase in internal sensitivity to obtain high sensitivity. The metal ion donating compounds concentrated on the surface layer of the silver halide particles may be contained by, for example, supplying the metal ion donating compounds in accordance with the addition of the aqueous silver salt solution and the aqueous halide solution for forming the surface layer after forming the silver halide particles (core) of a part other than the surface layer.

Various polyvalent metal ion impurities in a process of forming or physically maturing the emulsion particles in addition to the VIII group metals may be introduced into the silver halide emulsion used in the present invention. An addition amount of the compounds covers a wide range according to the intended use and 10⁻⁹ to 10⁻² moles are preferable on the basis of 1 mole of silver halide.

The silver halide emulsion used in the present invention is generally chemically sensitized. As a chemical sensitization method, there are a so-called gold sensitization method using a gold compound (for example, U.S. Pat. No. 2,448,060 and U.S. Pat. No. 3,320,069), a sensitization method using metals such as iridium, platinum, rhodium, and palladium (for example, U.S. Pat. Nos. 2,448,060, 2,566,245, and 2,566,263), a sulfur sensitization method using a sulfur-containing compound (for example, U.S. Pat. No. 2,222,264), selenium sensitization using a selenium compound, tellurium sensitization using a tellurium compound or a reduction sensitization method using tin salts, thiourea dioxide, and polyamine (for example, U.S. Pat. Nos. 2,487,850, 2,518,698, and 2,521,925). These sensitization methods may be used either alone or in combination.

A known gold sensitization is preferably conducted for the silver halide emulsion used in the present invention. The reason is that a variation in photographic performance when performing scanning exposure such as a laser beam may be further reduced by performing the gold sensitization. In order to perform the gold sensitization, compounds such as chlorauric acid or a salt thereof, gold thiocyanate, and gold thiosulfate may be used. The added amount of the compounds varies according to circumstances, but is 5×10⁻⁷ to 5×10⁻² moles and preferably 1×10⁻⁶ to 1×10⁻³ moles per 1 mole of the silver halide. The compounds are added until the chemical sensitization used in the present invention is completed.

In the present invention, it is also preferred that the gold sensitization is combined with other sensitization methods, for example, sulfur sensitization, selenium sensitization, tellurium sensitization, reduction sensitization, or noble metal sensitization using noble metals other than gold compounds.

Various compounds or precursors thereof may be added to the silver halide emulsion used in the present invention for the purpose of preventing fogging and stabilizing a photographic performance during a manufacturing process, preservation or a photographic processing of the photosensitive material. As a detailed example of the compounds, compounds described on pages 39 to 72 of Japanese Patent Application Laid-Open No. 62-215272 may be used. The emulsion used in the present invention is preferably a so-called surface latent image type emulsion in which a latent image is generally formed on the surface of a particle.

A thickness of one silver halide emulsion layer is preferably 0.5 μm or more and 5 μm or less, and particularly preferably 1 μm or more and 3 μm or less.

The number of silver halide emulsion layers may be one, but preferably one or more and ten or less, and particularly preferably one or more and three or less. The amount of silver contained in one layer is preferably 0.5 g/m² or more and 10 g/m² or less and particularly 1 g/m² or more 5 g/m² or less.

The amount of coated silver of the photosensitive material of the present invention is preferably 0.5 g/m² or more and 8.0 g/m² or less, more preferably 1.0 g/m² or more and 5.0 g/m² or less, and most preferably 1.5 g/m² or more and 3.0 g/m² or less in order to improve sharpness.

<Protective Layer>

It is preferred that the silver halide photographic photosensitive material of the present invention includes a protective layer which is provided on the emulsion layer formed on the support. The silver halide photographic photosensitive material may include a back layer on a rear surface of the support (side without the emulsion layer). The silver halide photographic photosensitive material may be formed with a back layer, a support, an antihalation layer, an emulsion layer, an intermediate layer, an ultraviolet absorption layer, and a protective layer. When a pigment or a dye is used in these layers, it is preferable to use methine compounds of the present invention because the compounds make decoloring easy.

As a protective colloid, acylated gelatin such as phthalated gelatin, malonated gelatin in addition to gelatin, cellulose compounds such as hydroxyethyl cellulose and carboxymethyl cellulose; a soluble starch such as dextrin; a hydrophilic polymer such as polyvinyl alcohol, polyvinyl pyrrolidone, polyacrylamide, or polystyrene sulfonate; a plasticizer for size stabilization; and a latex polymer, or a matting agent may be added to the silver halide photographic emulsion used in the present invention.

<Support>

A support of the silver halide photosensitive material of the present invention may be transparent preferably. As a support, a polyester film is suitable, and examples thereof may include polyethylene terephthalate and polyethylene naphthalate. Cellulose triacetate, cellulose acetate butyrate, and cellulose acetate propionate are also preferable. The polyester film may be at any time before successive biaxial stretching, before simultaneous biaxial stretching, before re-stretching after uniaxial stretching, or after biaxial stretching.

Among them, a polyethylene terephthalate film is preferable and a biaxially-stretched and thermally-fixed polyethylene terephthalate film is particularly preferably in terms of stability and toughness.

A thickness of the polyester support is not particularly limited and 15 μm to 500 μm is general and among them, 40 μm to 200 μm is preferable in terms of handling characteristics and versatility. A substrate may contain dyeable silicon, alumina sol, chromium salt, zirconium salt, and the like within the range where the transparency thereof can be maintained.

It is preferred that a surface of the substrate is subjected in advance to surface active treatment such as chemical treatment, mechanical treatment, corona discharge treatment, flame treatment, ultraviolet treatment, high-frequency treatment, glow discharge treatment, active plasma treatment, laser treatment, mixed acid treatment or ozone acid treatment, for the purpose of allowing a secure adhesion of an undercoating layer to the surface of the substrate.

Exposure for obtaining a photographic image may be performed by using a general method. That is, any one of known light sources such as natural light (sunlight), a tungsten lamp, a mercury lamp, a xenon arc lamp, a carbon arc lamp, a xenon flashlight, a laser, an LED, and a CRT may be used. An exposure time from 1/1000 seconds used in a general camera to 1 second may be used and further an exposure time shorter than 1/1000 seconds, for example, an exposure time of 1/104 to 1/108 a xenon fluorescent lamp may be used and an exposure time longer than 1 second may also be used. As necessary, a spectral composition of light used for exposure may be adjusted by a color filter. Laser light may also be used for exposure. In addition, exposure may be performed by light emitted from phosphors excited by an electron beam, an X-ray, a gamma ray, an alpha ray, and the like. A tungsten light source having exposure time from ⅕ seconds to 1 second is preferable.

The silver halide photographic photosensitive material of the present invention is particularly preferable as a negative film for recording motion picture sound and a negative film for preparing motion picture subtitles. An exposure method of the silver halide photographic photosensitive material of the present invention is not particularly limited, but it is preferable to overlap two sheets of photosensitive materials in which the developed silver halide photographic photosensitive material of the present invention and intermediate photosensitive material having image information are overlapped, and to closely expose the materials to a positive photosensitive material for a motion picture. A specific example of the exposure method may include a method of performing exposure with a tungsten light source by using a C type printer manufactured by Bell & Howell as a printer used when performing the exposure, but the exposure method is not limited thereto.

As a photographic processing of the photosensitive material of the present invention, a known method which is described on, for example, pp. 28-30 (RD-17643) of Issue 176 of Research Disclosure may be used and known processing liquid may be used for the photographic processing. A processing temperature is generally set between 18° C. and 50° C., but may be a temperature lower than 18° C. or a temperature higher than 50° C. As the photographic processing of the photosensitive material of the present invention, a developing processing of forming a silver image (black and white photographic processing) is preferably used.

As a black and white developer, known developing agents such as dihydroxybenzenes (for example, hydroquinone), 3-pyrazolidones (for example, 1-phenyl-3-pyrazolidone), and aminophenols (for example, N-methyl-p-aminophenol) may be used either alone or in combination.

In addition, those black and white developer described in, ^{┌}Photographic Processing Chemistry_{┘} written by L. F. A. Mason, pp. 226-229, published by the Focal Press (1966), U.S. Pat. Nos. 2,193,015 and 2,592,364, Japanese Patent Application Laid Open No. 48-64933, and the like may be used. The developer may further include a pH buffering agent such as alkali metal sulfite, carbonate, borate and phosphate, and a development inhibitor or an antifogging agent such as bromide and an organic antifogging agent. As necessary, the developer may include a hard water softening agent, a preservative such as hydroxylamine, an organic solvent such as benzyl alcohol and diethylene glycol, a development accelerator such as polyethylene glycol, quaternary ammonium salt, and amines, a fogging agent such as sodium boron hydride, an auxiliary developing agent such as 1-phenyl-3-pyrazolidone, a tackifier, a polycarboxylic acid-based chelating agent described in U.S. Pat. No. 4,083,723, and an antioxidant described in West German Patent (OLS) No. 2,622,950.

Among the above-mentioned development processings, the processing described in ^{┌}Processing KODAK Motion Picture Films, Module 15, Processing Black-and-White Films_{┘} of ^{┌}H-24 Processing Modules for Motion Picture Films_{┘} is most preferred.

Various additives, a development processing method, and the like which are used in the photosensitive material of the present invention are not particularly limited, and for example, those described in the following table may be preferably used.

TABLE 1

| Item | | Reference |
|---|---|---|
| 1) | Silver halide | Selenium sensitization method described from line 12 of the lower right |
| | emulsion and | column on page 20 to line 14 of the lower left column on page 21 of |
| | preparation | Japanese Patent Application Laid-Open No. 2-97937, from line 19 of the |
| | method thereof | upper right column on page 7 to line 12 of the lower left column on page |
| | | 8 of Japanese Patent Application Laid-Open No. 2-12236, and Japanese |
| | | Patent Application No. 3-189532 |
| 2) | Spectral | Spectral sensitization colorant described from line 8 of the upper left |
| | sensitization | column on page 7 to line 8 of the lower right column on page 8 of |
| | colorant (may be | Japanese Patent Application Laid-Open No. 2-55349, from line 8 of the |
| | in combination) | lower right column on page 7 to line 5 of the lower right column on page |
| | | 13 of Japanese Patent Application Laid-Open No. 2-39042, from line 13 |
| | | of the lower left column on page 8 to line 4 of the lower right column on |
| | | page 8 of Japanese Patent Application Laid-Open No. 2-12236, and |
| | | from line 3 of the lower right column on page 16 to line 20 of the lower |
| | | left column on page 17 of Japanese Patent Application Laid-Open No. 2- |
| | | 103536, and described in Japanese Patent Application Laid-Open Nos. |
| | | 1-112235, 2-124560 and 3-7928, and Japanese Patent Application Nos. |
| | | 3-189532 and 3-411064 |
| 3) | Hydrazine | General Formula (II) to Compound examples II-1 to II-54 described |
| | nucleating agent | from line 19 of the upper right column on page 2 to line 3 of the upper |
| | | right column on page 7 of Japanese Patent Application Laid-Open No. |
| | | 2-12236, and from line 1 of the lower right column on page 20 to line 20 |
| | | of the upper right column on page 27 of Japanese Patent Application |
| | | Laid-Open No. 3-174143 |
| 4) | Nucleating | General Formulas (II-m) to (II-p) and Compound examples II-1 to II-22 |
| | accelerator | described from line 13 of the upper right column on page 9 to line 10 of |
| | | the upper left column on page 16 of Japanese Patent Application Laid- |
| | | Open No. 2-103536, and compounds described in Japanese Patent |
| | | Application Laid-Open No. 1-179939 |

TABLE 2

| | | |
|---|---|---|
| 5) | Surface active | Descriptions from line 7 of the upper right column on page 9 to line 7 of |
| | agent | the lower right column on page 9 of Japanese Patent Application Laid- |
| | | Open No. 2-12236 and from line 13 of the lower left column on page 2 |
| | | to line 18 of the lower right column on page 4 of Japanese Patent |
| | | Application Laid-Open No. 2-18542 |
| 6) | Antifogging | Thiosulfinic acid compounds described from line 19 of the lower right |
| | agent | column on page 17 to line 4 of the upper right column on page 18 and |
| | | from lines 1 to 5 of the lower right column on page 18 of Japanese |
| | | Patent Application Laid-Open No. 2-103536 and described in Japanese |
| | | Patent Application Laid-Open No. 1-237538 |
| 7) | Polymer latex | Descriptions from lines 12 to 20 of the lower left column on page 18 of |
| | | Japanese Patent Application Laid-Open No. 2-103536 |
| 8) | Compound | Descriptions from line 6 of the lower right column on page 18 to line 1 |
| | having acid group | of the upper left column on page 19 of Japanese Patent Application |
| | | Laid-Open No. 2-103536 |
| 9) | Matting agent, | Descriptions from line 15 of the upper left column on page 19 to line 15 |
| | slipping agent, | of the upper right column on page 19 of Japanese Patent Application |
| | and plasticizer | Laid-Open No. 2-103536 |
| 10) | Polyhydroxybenzenes | Descriptions from line 9 of the upper left column on page 11 to line 17 |
| | | of the lower right column on page 11 of Japanese Patent Application |
| | | Laid-Open No. 2-55349 |
| 11) | Compound | Descriptions from line 6 of the lower right column on page 18 to line 1 |
| | having acid | of the upper left column on page 19 of Japanese Patent Application |
| | groups | Laid-Open No. 2-103536 and from line 13 of the lower right column on |
| | | page 8 to line 8 of the upper left column on page 11 of Japanese Patent |
| | | Application Laid-Open No. 2-55349 |
| 12) | Dye | Descriptions from lines 1 to 18 of the lower right column on page 17 of |
| | | Japanese Patent Application Laid-Open No. 2-103536 and from line 1 of |
| | | the upper right column on page 4 to line 5 of the upper right column on |
| | | page 6 of Japanese Patent Application Laid-Open No. 2-39042 |
| 13) | Binder | Descriptions from lines 1 to 20 of the lower right column on page 3 of |
| | | Japanese Patent Application Laid-Open No. 2-18542 |

TABLE 3

| | | |
|---|---|---|
| 14) | Black dot | Compounds described in U.S. Pat. No. 4,956,257 and Japanese Patent |
| | inhibitor | Application Laid-Open No. 1-118832 |
| 15) | Redox | Compounds (particularly, compound examples 1 to 50) represented by |
| | compound | the general Formula (I) in Japanese Patent Application Laid-Open No. 2- |
| | | 301743, the general Formulae (R-1), (R-2), and (R-3), and compound |
| | | examples 1 to 75 described on pages 3 to 20 of Japanese Patent |
| | | Application Laid-Open No. 3-174143, and compounds described in |
| | | Japanese Patent Application Nos. 3-69466 and 3-15648 |
| 16) | Monomethine | Compounds of the general Formula (II) (particularly, compound |
| | compound | examples II-1 to II-26) described in Japanese Patent Application Laid- |
| | | Open No. 2-287532 |
| 17) | Dihydroxybenzenes | Description from the upper left column on page 11 to the lower left |
| | | column on page 12 of Japanese Patent Application Laid-Open No. 3- |
| | | 39948 and compounds described in EP452772A |
| 18) | Developer | Descriptions from line 16 of the upper right column on page 19 to line 8 |
| | and development | of the upper left column on page 21 of Japanese Patent Application |
| | method | Laid-Open No. 2-103536 and from line 1 of the lower right column on |
| | | page 13 to line 10 of the upper left column on page 16 of Japanese |
| | | Patent Application Laid-Open No. 2-55349 |

Hereinafter, the present invention will be described in more detail with reference to Examples, but the present invention is not limited thereto.

### EXAMPLES

### Example 1

(Preparation of Silver Halide Emulsion)

A second solution and a third solution were added for 7 minutes to a first solution described in Table 4 kept at 65° C. while stirring, and subsequently 10.5 cc of a 10% aqueous potassium bromide solution, 6.5 cc of a 1N aqueous sodium hydroxide solution, and 10 cc of 0.05% 1-amino-iminosulfinic acid were added. Thereafter, a fourth solution and a fifth solution of Table 4 were added for 34 minutes while controlling pAg to be 7.15. 18 cc of 0.1% sodium ethylthiosulfonate and 18 cc of 0.001% iridium hexachloride were added at 29 minutes and at 31 minutes after the fourth solution and the fifth solution were started to add, respectively. 11 cc of 1N sulfuric acid and 400 g of a 10% aqueous gelatin solution were added. Finally, a monodispersed cubic silver iodobromide emulsion having an average equivalent spherical diameter of 0.23 μm and an average iodine content of 2 mole % was obtained (variation coefficient of the equivalent spherical diameter of 8%).

Thereafter, the emulsion was washed by using a flocculation method, gelatin and 9.6 g of phenoxyethanol were added, and pH was adjusted to 6.2 at 35° C. Subsequently, chemical sensitization was performed so as to achieve optimal sensitivity at 68° C. by adding chlorauric acid, potassium thiocyanate, sodium thiosulfate, and sensitizer 1. Compound 1 was added so that a variation in sensitivity after coating is minimized to obtain a silver iodobromide cubic emulsion 1 (an monodispersed cubic silver iodobromide emulsion having an average equivalent spherical diameter of 0.23 μm and an average iodine content of 2 mole %, and a variation coefficient of the equivalent spherical diameter of 8%).

TABLE 4
(Liquid 1)

| | | |
|---|---|---|
| Gelatin | 48 | g |
| Potassium bromide (10%) | 7.5 | ml |
| NaOH aqueous solution (1N) | 8.5 | ml |
| Adding water up to | 1266 | ml |

(Liquid 2)

| | | |
|---|---|---|
| Silver nitrate | 12.0 | g |
| NH₄NO₃ | 0.5 | g |
| Adding water up to | 276 | ml |

(Liquid 3)

| | | |
|---|---|---|
| Potassium bromide | 9.2 | g |
| Adding water up to | 273.6 | ml |

(Liquid 4)

| | | |
|---|---|---|
| Silver nitrate | 199 | g |
| NH₄NO₃ | 2.6 | g |
| Adding water up to | 655.7 | ml |

(Liquid 5)

| | | |
|---|---|---|
| Potassium bromide | 150.3 | g |
| Potassium Iodide | 42.8 | g |
| Adding water up to | 721.2 | ml |

Sensitizer 1 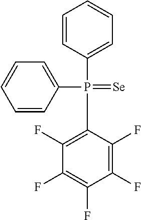
Compound 1

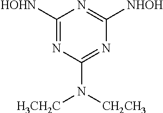

### Example 2

In the same manner as in Example 1, except that temperature where particles are formed is changed from 65° C. to 70° C., silver halide particles were formed to obtain monodispersed cubic silver iodobromide emulsion 2 having an average equivalent spherical diameter of 0.28 μm and an average iodine content of 2 mole % (variation coefficient of the equivalent spherical diameter of 8%).

### Example 3

Preparation of Photosensitive Material Sample 1

Preparation of coating liquid of first layer (AH layer)

| Gelatin | 2.0 | g/m² |
|---|---|---|
| Solid disperse dye 1 | Described in Table 5 or 6 | |
| Carbon particles | Described in Table 5 or 6 | |
| (manufactured by Mitsubishi | | |
| Chemical Corporation, MA220) | | |
| Oil-soluble dye 1 | 20 | mg/m² |
| Sodium polystyrene sulfonate | 12 | mg/m² |
| Dye 1 | 7 | mg/m² |
| Sodium dodecylbenzenesulfonate | 13 | mg/m² |
| Phosphoric acid | 4.5 | mgm² |
| Proxel (manufactured by Arch Chemical, Inc.) | 9 | mg/m² |

Solid disperse dye 1 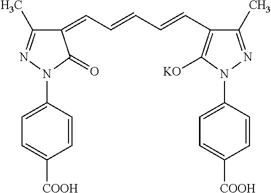
Oil-soluble dye 1 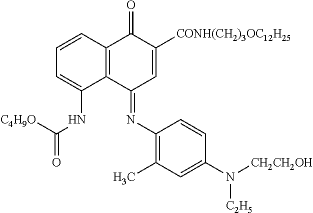
Dye 1

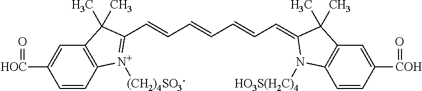

Preparation of coating liquid of second layer (photosensitive layer)

| | | |
|---|---|---|
| Silver iodobromide cubic emulsion 1 | 27.5 | g/m² |
| Gelatin | 0.5 | g/m² |
| Sensitizing dye 1 | 7.4 | mg/m² |
| Sensitizing dye 2 | 3.6 | mg/m² |
| Sodium polystyrene sulfonate | 97 | mg/m² |
| 4-hydroxy-6-methyl-1,3,3a,7-tetra-aza indene | 114 | mg/m² |
| 1-phenyl-5-mercaptotetrazole | 29 | mg/m² |
| Phosphoric acid | 90 | mg/m² |
| KBr | 23 | mg/m² |

Further, 2-bis(vinylsulfonyl acetamide)ethane as a hardener was added
to be at 207 mg/m².
Sensitizing dye 1 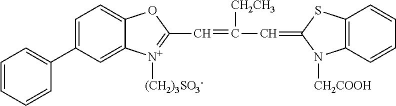
Sensitizing dye 2

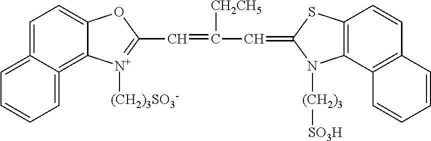

Preparation of coating liquid of third layer (protective layer)

| | | |
|---|---|---|
| Gelatin | 0.5 | mg/m² |
| Compound-2 | 2 | mg/m² |
| Compound-3 | 1 | mg/m² |
| Sodium dodecylbenzenesulfonate | 2 | mg/m² |
| Colloidal silica | 88 | mgm² |
| Compound-4 | 2 | mgm² |
| L-ascorbic acid | 20 | mg/m² |
| 1,5-dihydroxy-2-benzaldoxime | 5 | mg/m² |
| Sodium acetate | 100 | mg/m² |
| Sodium polystyrene sulfonate | 15 | mg/m² |
| Strontium sulfate | 30 | mg/m² |
| Compound-5 | 17 | mg/m² |
| Compound-6 | 6 | mg/m² |
| Liquid paraffin (KANTO KAGAKU) | 40 | mg/m² |
| Proxel (manufactured by Arch Chemical, Inc.) | 2 | mg/m² |

Compound 2 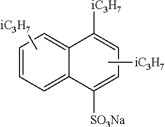
Compound 3 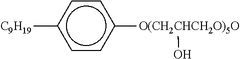
Compound 4 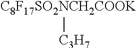 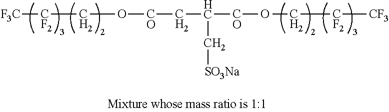
Compound 5
C₁₀H₂₁—O—(CH₂CH₂O)₂—(CH₂)₄—SO₃Na
Compound 6

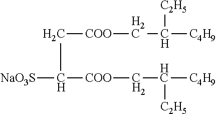

Liquids of first to third layers were simultaneously coated and dried on a polyethylene terephthalate support (ester support) which is undercoated to manufacture photosensitive material sample 1. Meanwhile, the first layer is coated to be a base material side. The resultant samples 1 to 7 were prepared.

Photosensitive material samples 8 to 11 were prepared in the same manner as in photosensitive material sample 1 except that silver idobromide cubic emulsion 1 of the second layer was changed to emulsions described in Table 5.

(Evaluation of Photographic Property)

(Exposure)

Exposure was performed for 1/8000 seconds by using a xenon lamp and a green filter (central wavelength 540 nm and half-value width 59 nm).

(Development Processing: Kodak D97 Processing)

The sample which was exposed as described above was subjected to development processing by the following processing process and processing liquid.

<Process>

| | | Processing | Supplementary |
|---|---|---|---|
| Process | Processing | time | amount (ml) (per |
| name | temperature (° C.) | (second) | 35 mm × 30.48 m) |
| 1. Developing | 21.0 ± 0.1 | 210 | 650 |
| 2. Water washing | 21 | 50 | 1200 |
| 3. Fixing | 21 | 360 | 600 |
| 4. Water washing | 21 | 600 | 1200 |
| 5. Drying | | | |

<Processing Liquid>

Composition per 1 liter is represented.

| | | | | Supplementary | |
|---|---|---|---|---|---|
| Process name | Name of chemicals | Tank liquid | | liquid | |
| Developing | Monol manufactured by | 0.5 | g | 0.7 | g |
| | Fujifilm Corporation | | | | |
| | Sodium sulfite | 40.0 | g | 70.0 | g |
| | Hydroquinone | 3.0 | g | 11.0 | g |
| | Manufactured by | | | | |
| | Fujifilm Corporation | | | | |
| | Sodium carbonate | 20.0 | g | 20.0 | g |
| | Sodium bromide | 1.75 | g | 1.30 | g |
| | Sodium hydroxide | — | | 2.0 | g |
| Fixing | Sodium thiosulfate | 153.0 | g | 153.0 | g |
| | Sodium sulfite | 15.0 | g | 15.0 | g |
| | Acetic acid (28%) | 48.0 | ml | 48.0 | ml |
| | Boric acid | 7.5 | g | 7.5 | g |
| | Potassium alum | 15.0 | g | 15.0 | g |

The reflection density of the samples after the completion of processing was measured using a thermal conductivity detector (TCD) type density measurement equipment manufactured by Fujifilm Corporation. Sensitivity was expressed as a reciprocal of an exposure amount required for giving color density higher than fogging density by 1.0 and was represented by a relative value when sensitivity of sample 1 is 100.

(Evaluation of Sharpness)

Sharpness was evaluated by modulation transfer function (MTF) measurements. The samples each were subjected to the aforementioned development processing by being exposed for 1/10 seconds with a xenon lamp by using an MTF measurement pattern. The MTF was measured with an aperture of 400×2 μm² and the sharpness was evaluated for a portion having an optical density of 1.0 by using an MTF value measured at a spatial frequency of 20 cycles/mm.

(Evaluation of Stability With Passage of Time)

After the samples were preserved in the dark site under a condition of 40° C. and 80%RH for three days (passage of time), the photographic property was measured and the stability with the passage of time was evaluated by a relative value when the sensitivity before the passage of time is 100. The results are shown in Table 5.

TABLE 5

| | | | | | | Sensitivity when time | |
|---|---|---|---|---|---|---|---|
| | Carbon | Solid disperse | | | Sensitivity before | passes in a high | |
| | particles | dye 1 | | | passage of time | humidity environment | |
| Photosensitive | (mg/m²⁾ | (mg/m²⁾ | Silver halide | | (relative value | (relative value when | |
| material sample | First layer | First layer | emulsion | | when sensitivity | sensitivity before the | |
| NOs | (AH layer) | (AH layer) | (size) | Sharpness | of sample 1 is 100) | passage of time is 100) | Remark |
| 1 | 0 | 0 | Emulsion 1 cube | 0.82 | 100 | 93 | Comparative |
| 2 | 25 | 0 | (0.23 μm) | 0.92 | 90 | 95 | Comparative |
| 3 | 35 | 0 | | 0.97 | 86 | 99 | Inventive |
| 4 | 50 | 0 | | 0.98 | 83 | 100 | Inventive |
| 5 | 0 | 15 | | 0.92 | 88 | 88 | Comparative |
| 6 | 0 | 21 | | 0.97 | 84 | 82 | Comparative |
| 7 | 0 | 31 | | 0.98 | 80 | 75 | Comparative |

From the results of Table 5, it could be seen that the photosensitive material according to the present invention exhibited an improvement effect in sharpness, and in the samples having the same sharpness, a variation in sensitivity (desensitization) was small even though time passed in a high humidity environment, as compared to a case where the solid disperse dye was utilized.

The dependence of carbon particle effect on the size of the silver halide particle and the dependence of carbon particle effect on the position where the carbon particle is coated were examined and the results are shown in Table 6. The carbon particles or dye were coated so that the sharpness becomes substantially equal in the samples of Table 6.

TABLE 6

| | | | Carbon | | | | Sensitivity when time | |
|---|---|---|---|---|---|---|---|---|
| | Carbon | Solid disperse | particles | | | Sensitivity before | passes in a high | |
| | particles | dye 1 | (mg/m²⁾ | | | passage of time | humidity environment | |
| Photosensitive | (mg/m²⁾ | (mg/m²⁾ | Second layer | Silver halide | | (relative value | (relative value when | |
| material sample | First layer | First layer | (photosensitive | emulsion cube | | when sensitivity | sensitivity before the | |
| NOs | (AH layer) | (AH layer) | layer) | (size) | Sharpness | of sample 1 is 100) | passage of time is 100) | Remark |
| 7 | 0 | 31 | 0 | Emulsion 1 | 0.98 | 80 | 75 | Comparative |
| 8 | 25 | 15 | 0 | (0.23 μm) | 0.98 | 81 | 85 | Comparative |
| 9 | 35 | 9 | 0 | | 0.98 | 83 | 98 | Inventive |
| 4 | 50 | 0 | 0 | | 0.98 | 83 | 100 | Inventive |
| 10 | 0 | 31 | 0 | Emulsion 2 | 0.88 | 116 | 83 | Comparative |
| 11 | 25 | 15 | 0 | (0.28 μm) | 0.88 | 118 | 88 | Comparative |
| 12 | 35 | 9 | 0 | | 0.89 | 120 | 98 | Inventive |
| 13 | 50 | 0 | 0 | | 0.89 | 120 | 100 | Inventive |
| 14 | 0 | 21 | 35 | Emulsion 1 | 0.99 | 76 | 93 | Comparative |
| 15 | 0 | 21 | 50 | (0.23 μm) | 0.99 | 69 | 93 | Comparative |
| 16 | 0 | 21 | 50 | | 0.99 | 69 | 93 | Comparative |

From the results of Table 6, it could be seen that the variation in sensitivity when time passed in a high humidity environment (desensitization due to high humidity) was particularly large when the silver halide particles having excellent sharpness and a small size were used. However, the photosensitive material having the carbon particle layer according to the present invention exhibited a little desensitization even the size of carbon particles is small. Further, an effect of improving desensitization due to a high humidity environment by the carbon particle layer of the present invention was large when the size of the carbon particles was small. As a result, both high sharpness and stable sensitivity can be achieved. Further, it could be seen that an effect of improving desensitization due to the passage of time in a high humidity environment was larger when the carbon particles were used in the first layer (AH layer) as the non-photosensitive layer, as compared to the case where the carbon particles were used in the photosensitive layer. In addition, the sensitivity before the passage of time was seriously diminished when the carbon particles were used in the photosensitive layer.

While the present invention has been shown and described with reference to certain exemplary embodiments thereof, it will be understood by those skilled in the art that various changes modifications may be made therein without departing from the spirit and scope of the present invention as defined by the appended claims.

What is claimed is:

1. A black and white silver halide photosensitive material, comprising:
a support;
at least one silver halide emulsion layer; and
at least one non-photosensitive layer,
wherein both of the silver halide emulsion layer and the non-photosensitive layer are positioned at one side of the support,
the non-photosensitive layer includes carbon particles of 35 mg/m² or more, and
the non-photosensitive layer is positioned closer to the support than all of the silver halide emulsion layers.

2. The black and white silver halide photosensitive material of claim 1,
wherein an average equivalent spherical diameter of silver halide particles included in the silver halide emulsion layer is 0.25 μm or less.

3. The black and white silver halide photosensitive material of claim 1,
wherein a shape of silver halide particles included in the silver halide emulsion layer is a cube.

4. The black and white silver halide photosensitive material of claim 1,
wherein the non-photosensitive layer further includes a solid disperse dye.

5. The black and white silver halide photosensitive material of claim 1,
wherein the non-photosensitive layer is an antihalation layer.

6. The black and white silver halide photosensitive material of claim 1,
wherein the non-photosensitive layer includes the carbon particles of 50 mg/m² or more.

7. The black and white silver halide photosensitive material of claim 1,
wherein the carbon particles has 10 nm to 500 nm in diameter.

8. The black and white silver halide photosensitive material of claim 1,
wherein the silver halide emulsion layer further contains at least one compound selected from the group consisting of chlorauric acid or a salt thereof, gold thiocyanate, and gold thiosulfate.

9. The black and white silver halide photosensitive material of claim 1,
wherein a thickness of the silver halide emulsion layer is 0.5 μm to 5 μm.

10. The black and white silver halide photosensitive material of claim 1,
wherein a thickness of the non-photosensitive layer is 0.2 μm to 10 μm.
